(19) United States
(12) Patent Application Publication
(10) Pub. No.: US 2026/0269848 A1
(43) Pub. Date: Sep. 10, 2026

(54) RADIO FREQUENCY CIRCUIT

(71) Applicant: Murata Manufacturing Co., Ltd., Nagaokakyo-shi (JP)

(72) Inventors: Morio TAKEUCHI, Nagaokakyo-shi (JP); Hiroyuki KANI, Nagaokakyo-shi (JP); Reiji NAKAJIMA, Nagaokakyo-shi (JP)

(73) Assignee: Murata Manufacturing Co., Ltd., Nagaokakyo-shi (JP)

(21) Appl. No.: 19/663,330

(22) Filed: Apr. 30, 2026

Related U.S. Application Data
(63) Continuation of application No. PCT/JP2024/034252, filed on Sep. 25, 2024.

(30) Foreign Application Priority Data
Nov. 9, 2023 (JP) 2023-191736

(51) Int. Cl. H04B 1/00; H04L 5/14

(52) U.S. Cl. CPC H04B 1/0057; H04L 5/1461

(57) ABSTRACT

A radio frequency circuit includes: a first switching circuit and a second switching circuit. The first switching circuit includes a first common terminal connected to an antenna connection terminal and first and second selection terminals. The second switching circuit includes a second common terminal connected to the first selection terminal and third and fourth selection terminals. A first transmission filter configured for a first power class (for example, Power Class 2), is connected to the second selection terminal. A first reception filter is connected to the third selection terminal. At least one of a second transmission filter or a second reception filter corresponding to a second power class lower than the first power class (for example, Power Class 3), is connected to the fourth selection terminal.

### CROSS-REFERENCE TO RELATED APPLICATIONS

This application is a continuation of International Application No. PCT/JP2024/034252, filed on Sep. 25, 2024, which claims the benefit of priority to Japanese Patent Application No. 2023-191736, filed on Nov. 9, 2023. The entire contents of each of these applications are hereby incorporated herein by reference.

### TECHNICAL FIELD

The present disclosure relates to a radio frequency circuit.

### BACKGROUND ART

Radiofrequency circuits corresponding to power classes (for example, Power Class 2) that allow maximum output power higher than that of conventional one have been proposed. For example, Patent Document 1 discloses a radio frequency circuit including a duplexer circuit connected to a power amplifier circuit corresponding to a first power class, and a duplexer circuit connected to a power amplifier circuit corresponding to a second power class.

### CITATION LIST

### Patent Document

Patent Document 1: International Publication No. 2022/138373

### SUMMARY

### Radio

A radio frequency circuit according to an aspect of the present disclosure includes: a first switching circuit including a first common terminal connected to an antenna connection terminal, a first selection terminal, and a second selection terminal; a second switching circuit including a second common terminal connected to the first selection terminal, a third selection terminal, and a fourth selection terminal; a first transmission filter connected to the second selection terminal and having a pass band including a transmission band of a first FDD band corresponding to a first power class defined by first maximum output power; a first reception filter connected to the third selection terminal and having a pass band including a reception band of the first FDD band; and at least one of a second transmission filter and a second reception filter connected to the fourth selection terminal, the second transmission filter having a pass band including a transmission band of a second band corresponding to a second power class defined by second maximum output power lower than the first maximum output power, the second reception filter having a pass band including a reception band of a third band.

### BRIEF DESCRIPTION OF DRAWINGS

FIG. 1 is a circuit configuration diagram of a radio frequency circuit according to an embodiment.

FIG. 2 is a circuit configuration diagram illustrating a first communication mode of the radio frequency circuit according to the embodiment.

FIG. 3 is a circuit configuration diagram illustrating a second communication mode of the radio frequency circuit according to the embodiment.

FIG. 4 is a circuit configuration diagram illustrating a third communication mode of the radio frequency circuit according to the embodiment.

FIG. 5 is a circuit configuration diagram illustrating a fourth communication mode of the radio frequency circuit according to the embodiment.

FIG. 6 is a circuit configuration diagram illustrating a fifth communication mode of the radio frequency circuit according to the embodiment.

FIG. 7 is a plan view of the radio frequency circuit according to the embodiment.

### DESCRIPTION OF EMBODIMENTS

However, the inventors have recognized that, in the technique described above, when a plurality of filters are required to correspond to a plurality of bands, loss of transmission signals by a switching circuit to which the plurality of filters are connected may be a problem.

Therefore, the present disclosure provides a radiofrequency circuit capable of reducing loss of transmission signals.

Hereinafter, embodiments of the present disclosure are described in detail with reference to the drawings. Note that every embodiment described below illustrates a comprehensive or specific example. Numerical values, shapes, materials, components, arrangement and connection modes of the components, and the like described in the following embodiments are examples and not intended to limit the present disclosure.

In each drawing referred to below, an x-axis and a y-axis are axes orthogonal to one another on a plane parallel to a main surface of a module substrate. Specifically, in a case in which the module substrate has a rectangular shape in plan view, the x-axis is parallel to a first side of the module substrate, and the y-axis is parallel to a second side orthogonal to the first side of the module substrate. Moreover, a z-axis is an axis perpendicular to the main surface of the module substrate, where a positive direction of the z-axis indicates an upper direction and a negative direction thereof indicates a lower direction.

Note that each drawing is a schematic diagram in which emphasis, omission, or adjustment of ratios is performed as appropriate to show the present disclosure, and is not necessarily strictly illustrated, and may show different shapes, positional relationships, and ratios from actual ones. In the drawings, substantially the same configurations are denoted by the same reference characters, and redundant description may be omitted or simplified.

In the present disclosure, “being connected” includes not only a case of being directly connected by a connection terminal and/or a wiring conductor but also a case of being electrically connected via another circuit element. “A is connected between B and C” means that A is connected in series to a path connecting B and C, and specifically means that one end of A is connected to B and the other end of A is connected to C. “Terminal” means a point where a conductor within an element ends. Note that when impedance of a conductor between elements is sufficiently low, a terminal can be interpreted as not only a single point but also any point on the conductor between the elements or the entire conductor.

“A pass band of a filter” is a frequency spectrum portion transmitted by a filter, and is defined as a frequency band in which output power does not attenuate by 3 dB or more from maximum output power. Therefore, a radio frequency end and a low frequency end of a pass band of a band pass filter are identified as a higher frequency and a lower frequency of two points where output power attenuates by 3 dB from the maximum output power.

“Reception band” means a frequency band used for reception in a communication device, and “transmission band” means a frequency band used for transmission in the communication device. For example, in a band for frequency division duplex (FDD), different frequency bands (an uplink band and a downlink band) are used for the transmission band and the reception band. Moreover, for example, in a band for time division duplex (TDD), the same frequency band is used for the transmission band and the reception band.

“A component is provided to a main surface of a substrate” includes, in addition to a component being disposed in contact with a main surface of a substrate, a component being disposed above the main surface without being in contact with the main surface (for example, the component being stacked on another component disposed in contact with the main surface). Moreover, “a component is provided to a main surface of a substrate” may include a component being disposed at a recess provided to a main surface.

“A is disposed between B and C” means that at least one of a plurality of line segments connecting any point in B and any point in C passes through A. “A is disposed closer than B to C” means that a distance between A and C is shorter than a distance between B and C. Here, “distance between A (B) and C” means a length of the shortest line segment among a plurality of line segments connecting any point in A (B) and any point in C.

“Plan view of a module substrate” means viewing an object by orthographic projection onto an xy plane from a z-axis positive side.

Moreover, terms indicating relationships between elements such as “parallel” and “perpendicular”, terms indicating shapes of elements such as “rectangular”, and numerical ranges indicate not only strict meanings but also substantially equivalent ranges, for example, including errors of approximately several percent.

### Embodiment

An embodiment will be described. A communication device 5 according to this embodiment can be used to provide wireless connection. For example, the communication device 5 can be implemented in user equipment (UE) in a cellular network (also referred to as a mobile network), such as a cellular phone, a smartphone, a tablet computer, and a wearable device. In another example, the communication device 5 is implemented, so that wireless connection can be provided to an internet of things (IoT) sensor device, a medical/healthcare device, a vehicle, an unmanned aerial vehicle (UAV) (so-called drone), or an automated guided vehicle (AGV). In still another example, the communication device 5 is implemented, so that wireless connection can also be provided at a wireless access point or a wireless hotspot.

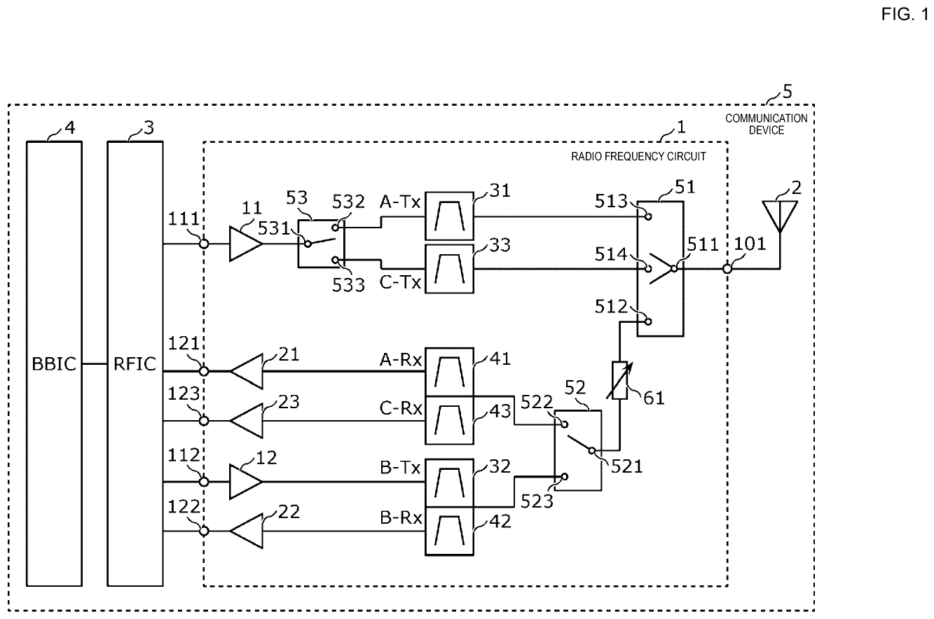

Circuit configurations of the communication device 5 and a radiofrequency circuit 1 according to this embodiment will be described with reference to FIG. 1. FIG. 1 is a circuit configuration diagram of the communication device 5 according to this embodiment.

Note that FIG. 1 is an exemplary circuit configuration, and the communication device 5 and the radiofrequency circuit 1 may be implemented by using any of a wide variety of circuit implementations and circuit technologies. Therefore, description of the communication device 5 and the radiofrequency circuit 1 provided below should not be construed in a limiting sense.

### 1. Circuit Configuration of Communication Device 5

First, the circuit configuration of the communication device 5 according to this embodiment will be described with reference to FIG. 1. The communication device 5 includes the radiofrequency circuit 1, an antenna 2, a radio frequency integrated circuit (RFIC) 3, and a baseband integrated circuit (BBIC) 4.

The radiofrequency circuit 1 can transmit a radiofrequency signal between the antenna 2 and the RFIC 3. The circuit configuration of the radiofrequency circuit 1 will be described later.

The antenna 2 is connected to an antenna connection terminal 101 of the radiofrequency circuit 1. The antenna 2 can receive a radiofrequency signal from the radiofrequency circuit 1 and output it to the outside of the communication device 5. Further, the antenna 2 can also receive a radiofrequency signal from the outside of the communication device 5 and output it to the radiofrequency circuit 1. Note that the antenna 2 is not necessarily included in the communication device 5. Further, the communication device 5 may further include one or more antennas in addition to the antenna 2.

The RFIC 3 is an example of a signal processing circuit that processes a radiofrequency signal. Specifically, the RFIC 3 can perform signal processing such as up-conversion to a transmission signal input from the BBIC 4, and output a radiofrequency transmission signal generated through the signal processing to the radiofrequency circuit 1. Furthermore, the RFIC 3 can perform signal processing such as down-conversion to a radiofrequency reception signal input via a reception path of the radiofrequency circuit 1, and output a reception signal generated through the signal processing to the BBIC 4. Moreover, the RFIC 3 may include a control unit that controls a switch, a power amplifier, and the like included in the radiofrequency circuit 1. Note that part or the entirety of the function as the control unit of the RFIC 3 may be included outside the RFIC 3, for example, in the BBIC 4 or the radiofrequency circuit 1.

The BBIC 4 is a baseband signal processing circuit that performs signal processing by using an intermediate frequency band having a lower frequency than a radiofrequency signal transmitted by the radiofrequency circuit 1. As a signal processed by the BBIC 4, for example, an image signal for image display and/or an audio signal for communication via a speaker is used. Note that the BBIC 4 is not necessarily included in the communication device 5.

### 2. Circuit Configuration of Radio Frequency Circuit 1

Next, the circuit configuration of the radiofrequency circuit 1 according to this embodiment will be described with reference to FIG. 1. The radiofrequency circuit 1 includes power amplifiers 11 and 12, low-noise amplifiers 21 to 23, transmission filters 31 to 33, reception filters 41 to 43, switching circuits 51 to 53, a variable phase circuit 61, the antenna connection terminal 101, radiofrequency input terminals 111 and 112, and radiofrequency output terminals 121 to 123.

The antenna connection terminal 101 is an outer connection terminal of the radiofrequency circuit 1. The antenna connection terminal 101 is connected to the antenna 2 outside of the radiofrequency circuit 1 and is connected to the switching circuit 51 inside of the radiofrequency circuit 1. Accordingly, the radiofrequency circuit 1 can supply a transmission signal to the antenna 2 and receive a reception signal from the antenna 2 via the antenna connection terminal 101.

The radiofrequency input terminals 111 and 112 are outer connection terminals of the radiofrequency circuit 1. The radiofrequency input terminals 111 and 112 are connected to the RFIC 3 outside of the radiofrequency circuit 1 and are connected to the power amplifiers 11 and 12, respectively, inside of the radiofrequency circuit 1. Accordingly, the radiofrequency circuit 1 can supply, to the power amplifier 11, transmission signals of bands A and C received from the RFIC 3 via the radiofrequency input terminal 111, and can supply, to the power amplifier 12, a transmission signal of a band B received from the RFIC 3 via the radiofrequency input terminal 112.

The radiofrequency output terminals 121 to 123 are outer connection terminals of the radiofrequency circuit 1. The radiofrequency output terminals 121 to 123 are connected to the RFIC 3 outside of the radiofrequency circuit 1 and are connected to the low noise amplifiers 21 to 23, respectively, inside of the radiofrequency circuit 1. Accordingly, the radiofrequency circuit 1 can supply, to the RFIC 3, reception signals of the bands A to C from the low noise amplifiers 21 to 23 via the radiofrequency output terminals 121 to 123.

The power amplifier 11 is connected between the radiofrequency input terminal 111 and the switching circuit 53. Specifically, an input end of the power amplifier 11 is connected to the radiofrequency input terminal 111, and an output end of the power amplifier 11 is connected to the switching circuit 53. The power amplifier 11 can use power supplied from a power source to amplify transmission signals of the bands A and C supplied from the RFIC 3 via the radiofrequency input terminal 111. The power amplifier 11 corresponds to a first power class.

The power amplifier 12 is connected between the radiofrequency input terminal 112 and the transmission filter 32. Specifically, an input end of the power amplifier 12 is connected to the radiofrequency input terminal 112, and an output end of the power amplifier 12 is connected to the transmission filter 32. The power amplifier 12 can use power supplied from a power source to amplify a transmission signal of the band B supplied from the RFIC 3 via the radiofrequency input terminal 112. The power amplifier 12 corresponds to a second power class but does not necessarily correspond to the first power class.

The power amplifiers 11 and 12 can include heterojunction bipolar transistors (HBT) and can be manufactured using a semiconductor material. As the semiconductor material, for example, silicon germanium (SiGe) or gallium arsenide (GaAs) can be used. Note that amplification transistors of the power amplifiers 11 and 12 are not limited to HBTs. For example, the power amplifier 11 may include a radioelectron mobility transistor (HEMT) or a metal-semiconductor field effect transistor (MESFET). In this case, gallium nitride (GaN) or silicon carbide (SiC) may be used as the semiconductor material.

Note that part or the entirety of the power amplifier 11 is not necessarily included in the radiofrequency circuit 1. In this case, part or the entirety of the power amplifier 11 may be connected between the RFIC 3 and the radiofrequency input terminal 111, or may be included in the RFIC 3. Similarly, part or the entirety of the power amplifier 12 is not necessarily included in the radiofrequency circuit 1. In this case, part or the entirety of the power amplifier 12 may be connected between the RFIC 3 and the radiofrequency input terminal 112, or may be included in the RFIC 3.

The first power class is a power class defined by first maximum output power. The first power class may be, for example, Power Class 2 defined by maximum output power of 26 dBm. The second power class is a power class defined by second maximum output power lower than the first maximum output power. The second power class may be, for example, Power Class 3 defined by maximum output power of 23 dBm. Note that the first power class and the second power class are not limited to Power Class 2 and Power Class 3, respectively. For example, the first power class may be Power Class 1.5, and the second power class may be Power Class 5.

The power class is a classification of terminal output power defined by maximum output power, and indicates that a smaller value of the power class allows higher maximum output power. For example, in 3GPP, maximum output power of Power Class 1 is defined as 31 dBm, maximum output power of Power Class 1.5 is defined as 29 dBm, maximum output power of Power Class 2 is defined as 26 dBm, maximum output power of Power Class 3 is defined as 23 dBm, and maximum output power of Power Class 5 is defined as 20 dBm.

Maximum output power of a terminal is defined by maximum output power at an antenna end. Maximum output power of UE is measured by a method defined by 3GPP or the like. For example, in FIG. 1, radiated power at the antenna 2 is measured to measure the maximum output power. Note that instead of measuring the radiated power, a terminal is provided at a vicinity of the antenna 2 and a measuring instrument (for example, a spectrum analyzer) is connected to the terminal, so that maximum output power of the antenna 2 can be measured.

The low noise amplifier 21 is connected between the reception filter 41 and the radiofrequency output terminal 121. Specifically, an input end of the low noise amplifier 21 is connected to the reception filter 41, and an output end of the low noise amplifier 21 is connected to the radiofrequency output terminal 121. The low noise amplifier 21 can use power supplied from a power source to amplify a reception signal of the band A that has passed through the reception filter 41.

The low noise amplifier 22 is connected between the reception filter 42 and the radiofrequency output terminal 122. Specifically, an input end of the low noise amplifier 22 is connected to the reception filter 42, and an output end of the low noise amplifier 22 is connected to the radiofrequency output terminal 122. The low noise amplifier 22 can use power supplied from a power source to amplify a reception signal of the band B that has passed through the reception filter 42.

The low noise amplifier 23 is connected between the reception filter 43 and the radiofrequency output terminal 123. Specifically, an input end of the low noise amplifier 23 is connected to the reception filter 43, and an output end of the low noise amplifier 23 is connected to the radiofrequency output terminal 123. The low noise amplifier 23 can use power supplied from a power source to amplify a reception signal of the band C that has passed through the reception filter 43.

The low noise amplifiers 21 to 23 can include field effect transistors (FET) and can be manufactured using a semiconductor material. As the semiconductor material, for example, silicon single crystal, gallium nitride (GaN), or silicon carbide (SiC) can be used. Note that amplification transistors of the low noise amplifiers 21 to 23 are not limited to FETs. For example, some or all of the low noise amplifiers 21 to 23 may include a bipolar transistor.

Note that part or the entirety of each of the low noise amplifiers 21 to 23 is not necessarily included in the radiofrequency circuit 1. In this case, part or the entirety of the low noise amplifier 21 may be connected between the radiofrequency output terminal 121 and the RFIC 3, part or the entirety of the low noise amplifier 22 may be connected between the radiofrequency output terminal 122 and the RFIC 3, and part or the entirety of the low noise amplifier 23 may be connected between the radiofrequency output terminal 123 and the RFIC 3. Moreover, part or the entirety of each of the low noise amplifiers 21 to 23 may be included in the RFIC 3.

The transmission filter 31 is an example of a first transmission filter and has a pass band including the transmission band of the band A. The transmission filter 31 has electric power handling capability corresponding to the first power class. The transmission filter 31 is connected between the switching circuits 51 and 53. Specifically, one end of the transmission filter 31 is connected to a selection terminal 513 of the switching circuit 51, and the other end of the transmission filter 31 is connected to a selection terminal 532 of the switching circuit 53.

The transmission filter 32 is an example of a second transmission filter and has a pass band including the transmission band of the band B. The transmission filter 32 has electric power handling capability corresponding to the second power class, but does not necessarily have electric power handling capability corresponding to the first power class. The transmission filter 32 is connected between the switching circuit 52 and the power amplifier 12. Specifically, one end of the transmission filter 32 is connected to a selection terminal 523 of the switching circuit 52, and the other end of the transmission filter 32 is connected to the output end of the power amplifier 12. Note that the transmission filter 32 is not necessarily included in the radiofrequency circuit 1.

The transmission filter 33 is an example of a third transmission filter and has a pass band including the transmission band of the band C. The transmission filter 33 has electric power handling capability corresponding to the first power class. The transmission filter 33 is connected between the switching circuits 51 and 53. Specifically, one end of the transmission filter 33 is connected to a selection terminal 514 of the switching circuit 51, and the other end of the transmission filter 33 is connected to a selection terminal 533 of the switching circuit 53. Note that the transmission filter 33 is not necessarily included in the radiofrequency circuit 1. In this case, the switching circuit 51 does not necessarily include the selection terminal 514.

As the transmission filters 31 to 33, a surface acoustic wave (SAW) filter, a bulk acoustic wave (BAW) filter, an LC resonance filter, a dielectric resonance filter, or any combination thereof may be used, and furthermore, the transmission filters 31 to 33 are not limited to these. For example, the transmission filters 31 and 33 may be BAW filters having higher electric power handling capability, and the transmission filter 32 may be a SAW filter having lower electric power handling capability.

The reception filter 41 is an example of a first reception filter and has a pass band including the reception band of the band A. The reception filter 41 is connected between the switching circuit 52 and the low noise amplifier 21. Specifically, one end of the reception filter 41 is connected to a selection terminal 522 of the switching circuit 52, and the other end of the reception filter 41 is connected to the input end of the low noise amplifier 21.

The reception filter 42 is an example of a second reception filter and has a pass band including the reception band of the band B. The reception filter 42 is connected between the switching circuit 52 and the low noise amplifier 22. Specifically, one end of the reception filter 42 is connected to the selection terminal 523 of the switching circuit 52, and the other end of the reception filter 42 is connected to the input end of the low noise amplifier 22. Note that the reception filter 42 is not necessarily included in the radiofrequency circuit 1. Moreover, the pass band of the reception filter 42 does not necessarily include the reception band of the band B, and may include a reception band of another band. In this case, the reception filter 42 may be connected to an additional selection terminal of the switching circuit 52.

The reception filter 43 is an example of a third reception filter and has a pass band including the reception band of the band C. The reception filter 43 is connected between the switching circuit 52 and the low noise amplifier 23. Specifically, one end of the reception filter 43 is connected to the selection terminal 522 of the switching circuit 52, and the other end of the reception filter 43 is connected to the input end of the low noise amplifier 23. Note that the reception filter 43 is not necessarily included in the radiofrequency circuit 1. Moreover, the reception filter 43 is not necessarily connected to the selection terminal 522, and may be connected to an additional selection terminal of the switching circuit 52.

As the reception filters 41 to 43, a SAW filter, a BAW filter, an LC resonance filter, a dielectric resonance filter, or any combination thereof may be used, and furthermore, the reception filters 41 to 43 are not limited to these.

The bands A to C are frequency bands for a communication system constructed by using the radio access technology (RAT). The bands A to C are defined in advance by a standardization body or the like (for example, the 3rd Generation Partnership Project (3GPP) (registered trademark) and Institute of Electrical and Electronics Engineers (IEEE)). Examples of the communication system include the 5th generation new radio (5G NR) system, the long term evolution (LTE) system, and the wireless local area network (WLAN) system.

The band A is an example of a first FDD band and corresponds to the first power class. The band A is an FDD band, and is, for example, Band 1 for LTE or n1 for 5G NR. Moreover, for example, the band A may be Band 3 for LTE or n3 for 5G NR, or may be Band 40 for LTE or n40 for 5G NR.

The band B is an example of a second band and a third band, and does not correspond to the first power class. The band B may be an FDD band or may be a TDD band. When the band B is a TDD band, the transmission filter 32 and the reception filter 42 may be integrated into one transmission/reception filter. The band B is, for example, Band 25 for LTE or n25 for 5G NR. Moreover, for example, the band B may be Band 66 for LTE or n66 for 5G NR.

The band C is an example of a fourth FDD band and corresponds to the first power class. The band C is an FDD band different from the band A, and is, for example, Band 3 for LTE or n3 for 5G NR. Moreover, for example, the band C may be Band 1 for LTE or n1 for 5G NR, or may be Band 40 for LTE or n40 for 5G NR.

The switching circuit 51 is an example of a first switching circuit and may be referred to as an antenna switch. The switching circuit 51 is connected between the antenna connection terminal 101 and the transmission filters 31 and 32, and between the antenna connection terminal 101 and the switching circuit 52. Specifically, the switching circuit 51 includes a common terminal 511 and selection terminals 512 to 514. The common terminal 511 is an example of a first common terminal and is connected to the antenna connection terminal 101. The selection terminal 512 is an example of a first selection terminal and is connected to a common terminal 521 of the switching circuit 52 via the variable phase circuit 61. The selection terminal 513 is an example of a second selection terminal and is connected to the transmission filter 31. The selection terminal 514 is an example of a fifth selection terminal and is connected to the transmission filter 33.

In such a connection configuration, the switching circuit 51 can connect the common terminal 511 to at least one of the selection terminals 512 to 514 based on, for example, a control signal from the RFIC 3. That is, in the switching circuit 51, the common terminal 511 can be connected to any of the selection terminals 512 to 514, and furthermore, can also be simultaneously connected to at least two of the selection terminals 512 to 514. The switching circuit 51 includes, for example, a multi-connection type switching circuit.

The switching circuit 52 is an example of a second switching circuit and may be referred to as an antenna switch. The switching circuit 52 is connected between the switching circuit 51 and the transmission filter 32, and between the switching circuit 51 and the reception filters 41 to 43. Specifically, the switching circuit 52 includes the common terminal 521 and the selection terminals 522 and 523. The common terminal 521 is an example of a second common terminal and is connected to the selection terminal 512 of the switching circuit 51 via the variable phase circuit 61. The selection terminal 522 is an example of a third selection terminal and is connected to the reception filters 41 and 43. The selection terminal 523 is an example of a fourth selection terminal and is connected to the transmission filter 32 and the reception filter 42.

In such a connection configuration, the switching circuit 52 can connect the common terminal 521 to at least one of the selection terminals 522 and 523 based on, for example, a control signal from the RFIC 3. That is, in the switching circuit 52, the common terminal 521 can be connected to either the selection terminal 522 or 523, and furthermore, can also be simultaneously connected to both of the selection terminals 522 and 523. The switching circuit 52 includes, for example, a multi-connection type switching circuit.

The switching circuit 53 is an example of a third switching circuit and may be referred to as a band select switch. The switching circuit 53 is connected between the power amplifier 11 and the transmission filters 31 and 33. Specifically, the switching circuit 53 includes a common terminal 531 and the selection terminals 532 and 533. The common terminal 531 is an example of a third common terminal and is connected to the output end of the power amplifier 11. The selection terminal 532 is an example of a sixth selection terminal and is connected to the transmission filter 31. The selection terminal 533 is an example of a seventh selection terminal and is connected to the transmission filter 33.

In such a connection configuration, the switching circuit 53 can exclusively connect the common terminal 531 to the selection terminals 532 and 533 based on, for example, a control signal from the RFIC 3. The switching circuit 53 includes, for example, a single-pole double-throw (SPDT) type switching circuit.

The switching circuits 51 and 53 are implemented by complementary metal-oxide-semiconductor silicon-on-insulator (CMOS-SOI), and the switching circuit 52 is implemented by bulk CMOS. Note that the method for implementing the switching circuits 51 to 53 is not limited to this. For example, the switching circuits 51 and/or 53 may be implemented by bulk CMOS, and the switching circuit 52 may be implemented by CMOS-SOI.

The variable phase circuit 61 is connected between the switching circuits 51 and 52. Specifically, the variable phase circuit 61 is connected between the selection terminal 512 of the switching circuit 51 and the common terminal 521 of the switching circuit 52. The variable phase circuit 61 can adjust a phase shift amount in accordance with the filter connected to the common terminal 511.

For example, when the transmission filter 31 and the reception filter 41 are simultaneously connected to the common terminal 511 for transmission and reception of a signal of the band A, a phase shift amount of the variable phase circuit 61 is adjusted to a phase shift amount that can bring impedance in the transmission band of the band A closer to an open state when the reception filter 41 is seen from the common terminal 511. Accordingly, it is possible to suppress intermodulation distortion and the like caused by leakage of a transmission signal of the band A to a reception path.

Moreover, for example, when the transmission filter 33 and the reception filter 43 are simultaneously connected to the common terminal 511 for transmission and reception of a signal of the band C, a phase shift amount of the variable phase circuit 61 is adjusted to a phase shift amount that can bring impedance in the transmission band of the band C closer to an open state when the reception filter 43 is seen from the common terminal 511. Accordingly, it is possible to suppress intermodulation distortion and the like caused by leakage of a transmission signal of the band C to a reception path.

Note that the circuit configuration of the variable phase circuit 61 is not particularly limited. For example, the variable phase circuit 61 may include an inductor and/or a capacitor and a switch. Note that the variable phase circuit 61 is not necessarily included in the radiofrequency circuit 1.

### 3. Communication Mode of Radio Frequency Circuit 1

Next, a communication mode of the radiofrequency circuit 1 corresponding to a band used for communication and a power class applied for the band will be described.

### 3.1. First Communication Mode

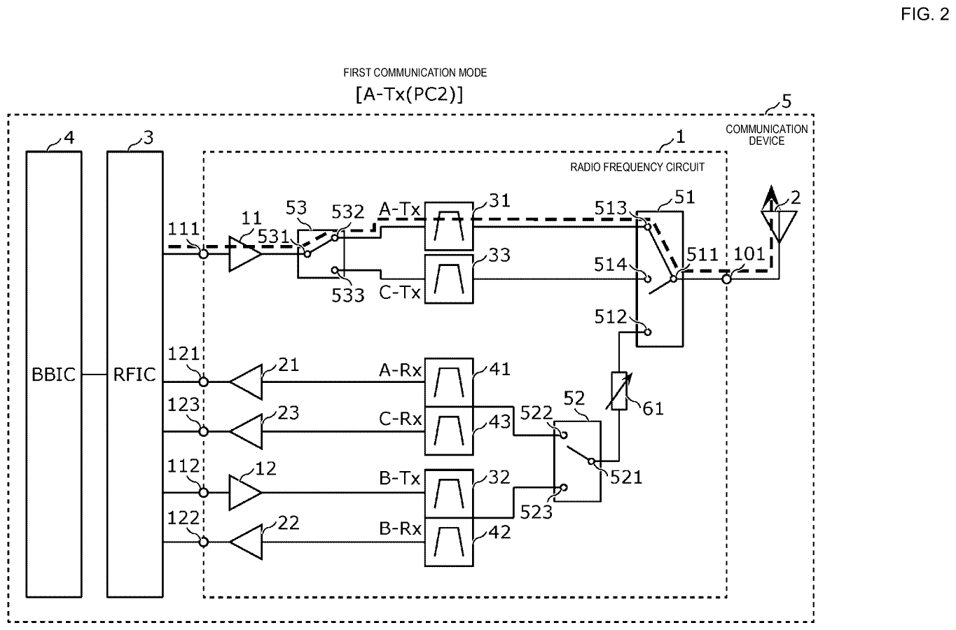

First, a first communication mode of the radiofrequency circuit 1 will be described with reference to FIG. 2. FIG. 2 is a circuit configuration diagram illustrating the first communication mode of the radiofrequency circuit 1 according to this embodiment. In this drawing and subsequent drawings, broken arrows indicate a flow of a radiofrequency signal.

The first communication mode is a communication mode for transmitting a signal of the band A in the first power class (for example, Power Class 2). In the first communication mode, transmission of a signal in the transmission band of the band A is not performed simultaneously with reception of a signal in the reception band of the band A.

In the first communication mode, the switching circuit 51 connects the common terminal 511 to the selection terminal 513 and does not connect the common terminal 511 to the selection terminals 512 and 514. Furthermore, the switching circuit 53 connects the common terminal 531 to the selection terminal 532 and does not connect the common terminal 531 to the selection terminal 533. Accordingly, one end of the transmission filter 31 is connected to the antenna connection terminal 101 via the switching circuit 51, and the other end of the transmission filter 31 is connected to the power amplifier 11 via the switching circuit 53.

As a result, a transmission signal of the band A is transmitted from the RFIC 3 to the antenna 2 via the radiofrequency input terminal 111, the power amplifier 11, the switching circuit 53, the transmission filter 31, the switching circuit 51, and the antenna connection terminal 101.

### 3.2. Second Communication Mode

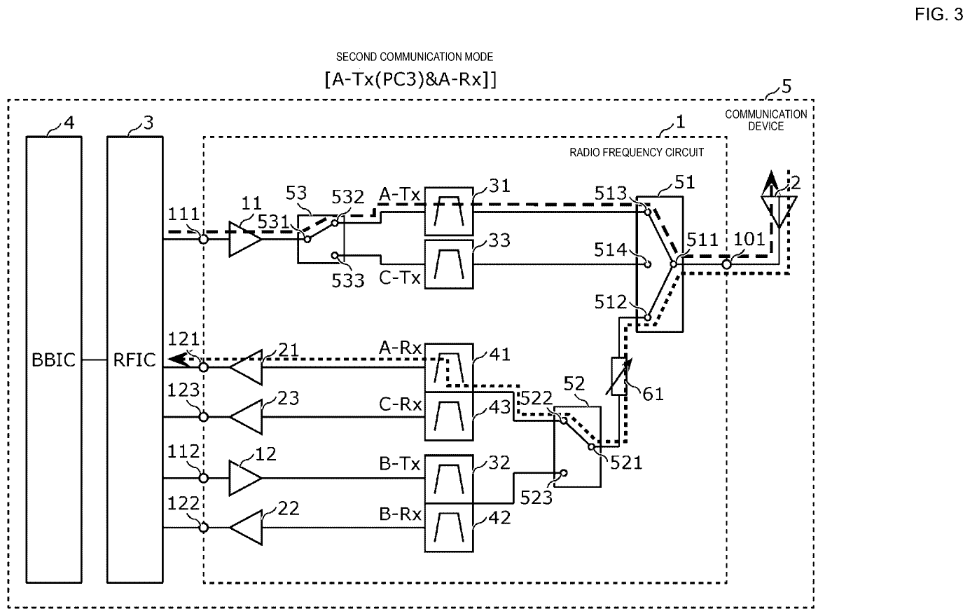

Next, a second communication mode of the radiofrequency circuit 1 will be described with reference to FIG. 3. FIG. 3 is a circuit configuration diagram illustrating the second communication mode of the radiofrequency circuit 1 according to this embodiment.

The second communication mode is a communication mode for transmitting and receiving a signal of the band A in the second power class (for example, Power Class 3). In the second communication mode, transmission of a signal in the transmission band of the band A is performed simultaneously with reception of a signal in the reception band of the band A.

In the second communication mode, the switching circuit 51 connects the common terminal 511 to the selection terminals 512 and 513 and does not connect the common terminal 511 to the selection terminal 514. Furthermore, the switching circuit 52 connects the common terminal 521 to the selection terminal 522 and does not connect the common terminal 521 to the selection terminal 523. Moreover, the switching circuit 53 connects the common terminal 531 to the selection terminal 532 and does not connect the common terminal 531 to the selection terminal 533. Accordingly, one end of the transmission filter 31 is connected to the antenna connection terminal 101 via the switching circuit 51, and the other end of the transmission filter 31 is connected to the power amplifier 11 via the switching circuit 53. Furthermore, one end of the reception filter 41 is connected to the antenna connection terminal 101 via the switching circuit 52, the variable phase circuit 61, and the switching circuit 51.

As a result, a transmission signal of the band A is transmitted from the RFIC 3 to the antenna 2 via the radiofrequency input terminal 111, the power amplifier 11, the switching circuit 53, the transmission filter 31, the switching circuit 51, and the antenna connection terminal 101. Moreover, a reception signal of the band A is transmitted from the antenna 2 to the RFIC 3 via the antenna connection terminal 101, the switching circuit 51, the variable phase circuit 61, the switching circuit 52, the reception filter 41, the low noise amplifier 21, and the radiofrequency output terminal 121.

### 3.3. Third Communication Mode

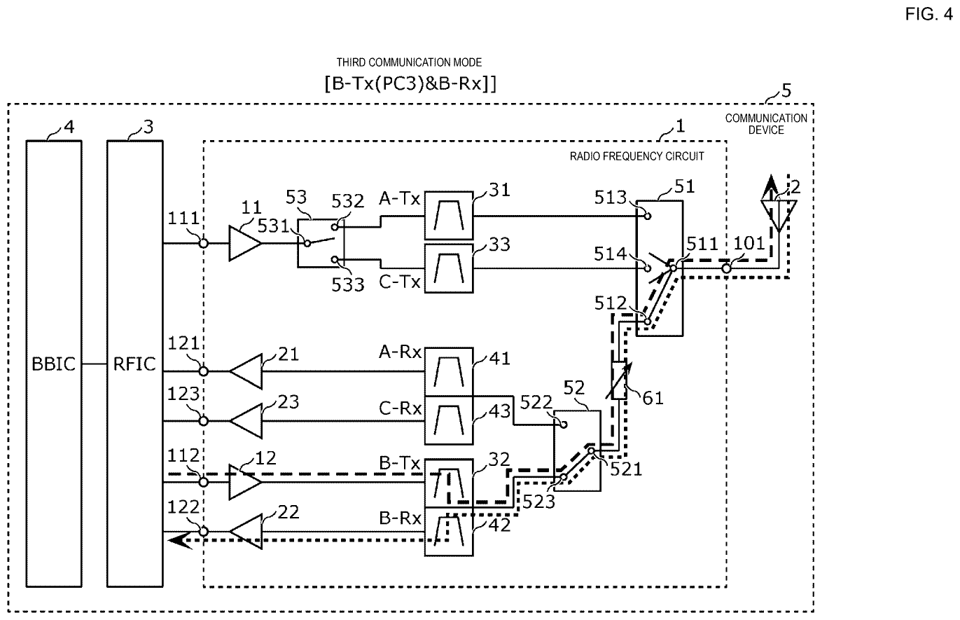

Next, a third communication mode of the radiofrequency circuit 1 will be described with reference to FIG. 4. FIG. 4 is a circuit configuration diagram illustrating the third communication mode of the radiofrequency circuit 1 according to this embodiment.

The third communication mode is a communication mode for transmitting and receiving a signal of the band B in the second power class (for example, Power Class 3). In the third communication mode, transmission of a signal in the transmission band of the band B is performed simultaneously with reception of a signal in the reception band of the band B.

In the third communication mode, the switching circuit 51 connects the common terminal 511 to the selection terminal 512 and does not connect the common terminal 511 to the selection terminals 513 and 514. Furthermore, the switching circuit 52 connects the common terminal 521 to the selection terminal 523 and does not connect the common terminal 521 to the selection terminal 522. Accordingly, one ends of the transmission filter 32 and the reception filter 42 are connected to the antenna connection terminal 101 via the switching circuit 52, the variable phase circuit 61, and the switching circuit 51.

As a result, a transmission signal of the band B is transmitted from the RFIC 3 to the antenna 2 via the radiofrequency input terminal 112, the power amplifier 12, the transmission filter 32, the switching circuit 52, the variable phase circuit 61, the switching circuit 51, and the antenna connection terminal 101. Moreover, a reception signal of the band B is transmitted from the antenna 2 to the RFIC 3 via the antenna connection terminal 101, the switching circuit 51, the variable phase circuit 61, the switching circuit 52, the reception filter 42, the low noise amplifier 22, and the radiofrequency output terminal 122.

### 3.4. Fourth Communication Mode

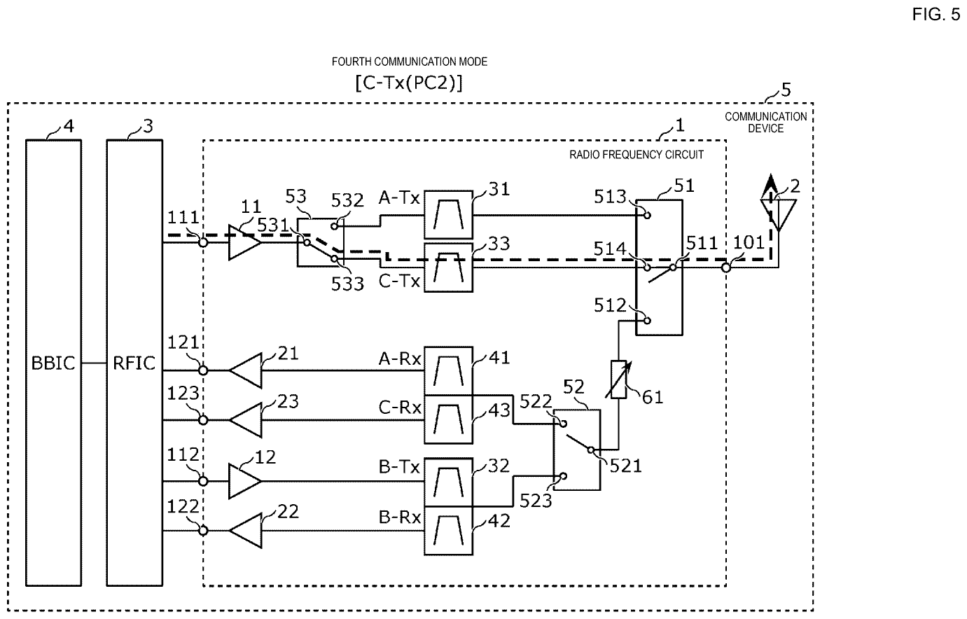

Then, a fourth communication mode of the radiofrequency circuit 1 will be described with reference to FIG. 5. FIG. 5 is a circuit configuration diagram illustrating the fourth communication mode of the radiofrequency circuit 1 according to this embodiment.

The fourth communication mode is a communication mode for transmitting a signal of the band C in the first power class (for example, Power Class 2). In the fourth communication mode, transmission of a signal in the transmission band of the band C is not performed simultaneously with reception of a signal in the reception band of the band C.

In the fourth communication mode, the switching circuit 51 connects the common terminal 511 to the selection terminal 514 and does not connect the common terminal 511 to the selection terminals 512 and 513. Furthermore, the switching circuit 53 connects the common terminal 531 to the selection terminal 533 and does not connect the common terminal 531 to the selection terminal 532. Accordingly, one end of the transmission filter 33 is connected to the antenna connection terminal 101 via the switching circuit 51, and the other end of the transmission filter 33 is connected to the power amplifier 11 via the switching circuit 53.

As a result, a transmission signal of the band C is transmitted from the RFIC 3 to the antenna 2 via the radiofrequency input terminal 111, the power amplifier 11, the switching circuit 53, the transmission filter 33, the switching circuit 51, and the antenna connection terminal 101.

### 3.5. Fifth Communication Mode

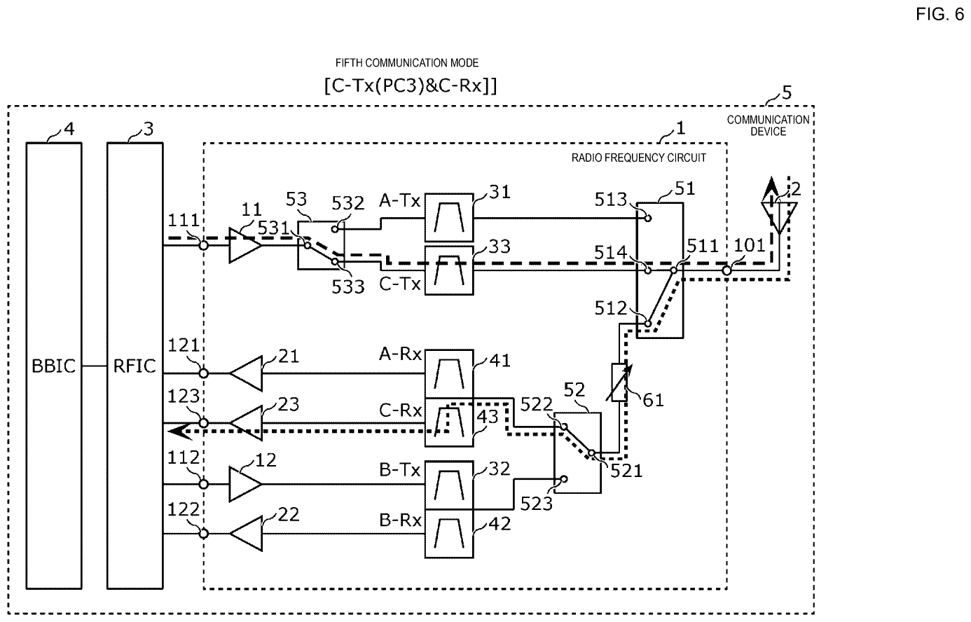

Next, a fifth communication mode of the radiofrequency circuit 1 will be described with reference to FIG. 6. FIG. 6 is a circuit configuration diagram illustrating the fifth communication mode of the radiofrequency circuit 1 according to this embodiment.

The fifth communication mode is a communication mode for transmitting and receiving a signal of the band C in the second power class (for example, Power Class 3). In the fifth communication mode, transmission of a signal in the transmission band of the band C is performed simultaneously with reception of a signal in the reception band of the band C.

In the fifth communication mode, the switching circuit 51 connects the common terminal 511 to the selection terminals 512 and 514 and does not connect the common terminal 511 to the selection terminal 513. Furthermore, the switching circuit 52 connects the common terminal 521 to the selection terminal 522 and does not connect the common terminal 521 to the selection terminal 523. Moreover, the switching circuit 53 connects the common terminal 531 to the selection terminal 533 and does not connect the common terminal 531 to the selection terminal 532. Accordingly, one end of the transmission filter 33 is connected to the antenna connection terminal 101 via the switching circuit 51, and the other end of the transmission filter 33 is connected to the power amplifier 11 via the switching circuit 53. Furthermore, one end of the reception filter 43 is connected to the antenna connection terminal 101 via the switching circuit 52, the variable phase circuit 61, and the switching circuit 51.

As a result, a transmission signal of the band C is transmitted from the RFIC 3 to the antenna 2 via the radiofrequency input terminal 111, the power amplifier 11, the switching circuit 53, the transmission filter 33, the switching circuit 51, and the antenna connection terminal 101. Moreover, a reception signal of the band C is transmitted from the antenna 2 to the RFIC 3 via the antenna connection terminal 101, the switching circuit 51, the variable phase circuit 61, the switching circuit 52, the reception filter 43, the low noise amplifier 23, and the radiofrequency output terminal 123.

### 4. Mounting Example of Radio Frequency Circuit 1

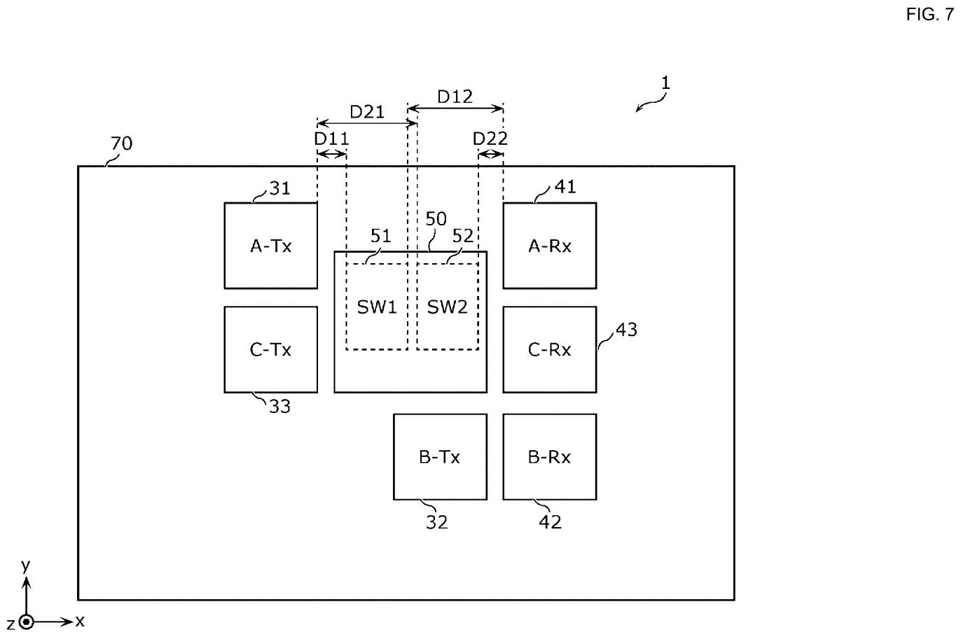

Next, a mounting example of the radiofrequency circuit 1 configured as described above will be described with reference to FIG. 7. FIG. 7 is a plan view of the radiofrequency circuit 1 according to this embodiment. In FIG. 7, some components are labeled with characters (for example, A-Tx) indicating themselves to facilitate understanding of arrangement relationship of the components, but actual components do not need to be labeled with these characters.

Note that in FIG. 7, illustration of some of a plurality of circuit components included in the radiofrequency circuit 1 is omitted. Circuit components e.g., the power amplifiers 11 and 12, may be disposed at any positions of a module substrate.

A module substrate 70 is a substrate on which the radiofrequency circuit 1 is mounted. In FIG. 7, a main surface of the module substrate 70 is provided with the transmission filters 31 (A-Tx), 32 (B-Tx), and 33 (C-Tx), the reception filters 41 (A-Rx), 42 (B-Rx), and 43 (C-Rx), and an integrated circuit 50 including the switching circuits 51 (SW1) and 52 (SW2).

As the module substrate 70, for example, a low temperature co-fired ceramics (LTCC) substrate or a high temperature co-fired ceramics (HTCC) substrate having a stacked structure of a plurality of dielectric layers, a component-embedded substrate, a substrate having a redistribution layer (RDL), a printed circuit board, or the like can be used, but the module substrate 70 is not limited thereto.

The integrated circuit 50 is disposed between the transmission filter 31 and the reception filter 41, and between the transmission filter 33 and the reception filter 43. That is, the switching circuits 51 and 52 in the integrated circuit 50 are disposed between the transmission filter 31 and the reception filter 41, and between the transmission filter 33 and the reception filter 43.

In the integrated circuit 50, the switching circuit 51 is closer than the switching circuit 52 to the transmission filter 31. That is, a distance D11 between the switching circuit 51 and the transmission filter 31 is shorter than a distance D21 between the switching circuit 52 and the transmission filter 31. Moreover, in the integrated circuit 50, the switching circuit 52 is closer than the switching circuit 51 to the reception filter 41. That is, a distance D22 between the switching circuit 52 and the reception filter 41 is shorter than a distance D12 between the switching circuit 51 and the reception filter 41. By disposing the first switching circuit 51 closer to the first transmission filter 31 than the second switching circuit 52, e.g., D11 <D21, the physical wiring length for high-power signals is minimized, thereby further reducing insertion loss.

The number of a plurality of field effect transistors (FET) connected in series between the common terminal 511 and each of the selection terminals 512 and 513 in the switching circuit 51 is greater than the number of a plurality of FETs connected in series between the common terminal 521 and each of the selection terminals 522 and 523 in the switching circuit 52. That is, a stack number of each of a plurality of series single-pole single-throw (SPST) switches included in the switching circuit 51 is greater than a stack number of each of a plurality of series SPST switches included in the switching circuit 52.

Note that in FIG. 7, the switching circuits 51 and 52 are implemented in a single integrated circuit 50, but they are not limited thereto. For example, the switching circuits 51 and 52 may be individually implemented in respective ones of two integrated circuits.

### 5. Summary

As described above, the radiofrequency circuit 1 according to this embodiment includes the switching circuit 51, the switching circuit 52, the transmission filter 31, the reception filter 41, and at least one of the transmission filter 32 and the reception filter 42 connected to the selection terminal 523. The switching circuit 51 includes the common terminal 511 connected to the antenna connection terminal 101 and the selection terminals 512 and 513. The switching circuit 52 includes the common terminal 521 connected to the selection terminal 512 and the selection terminals 522 and 523. The transmission filter 31 is connected to the selection terminal 513 and has the pass band including the transmission band of the band A corresponding to the first power class (for example, Power Class 2) defined by the first maximum output power. The reception filter 41 is connected to the selection terminal 522 and has the pass band including the reception band of the band A. The transmission filter 32 has the pass band including the transmission band of the band B corresponding to the second power class (for example, Power Class 3) defined by the second maximum output power lower than the first maximum output power. The reception filter 42 has the pass band including the reception band of the band B.

Accordingly, the reception filter 41, and the reception filter 42 and/or the transmission filter 32 are connected to the switching circuit 51 via the switching circuit 52. Thereby, the number of selection terminals of the switching circuit 51 can be reduced as compared with a case in which the reception filter 41, and the reception filter 42 and/or the transmission filter 32 are directly connected to the selection terminal of the switching circuit 51. Therefore, off-state capacitance of the selection terminal in the switching circuit 51 can be reduced, which can reduce loss of a transmission signal of the band A.

Moreover, for example, in the radiofrequency circuit 1 according to this embodiment, when the band A is used in the first power class, the common terminal 511 may be connected to the selection terminal 513 and is not necessarily connected to the selection terminal 512. When the band A is used in the second power class, the common terminal 511 may be connected to the selection terminals 512 and 513, and the common terminal 521 may be connected to the selection terminal 522.

Accordingly, when the band A is used in the first power class, the common terminal 511 is not connected to the selection terminal 512. Therefore, since a transmission signal in the first power class is not transmitted to the switching circuit 52, electric power handling capability of the switching circuit 52 can be made lower than electric power handling capability of the switching circuit 51. As a result, an increase in size of the radiofrequency circuit 1 due to the switching circuit 52 can be suppressed, which can achieve downsizing of the radiofrequency circuit 1 as a result of downsizing of the switching circuit 51 by a reduction in the number of selection terminals of the switching circuit 51.

Moreover, for example, in the radiofrequency circuit 1 according to this embodiment, the number of the plurality of FETs connected in series between the common terminal 511 and each of the selection terminals 512 and 513 in the switching circuit 51 may be greater than the number of the plurality of FETs connected in series between the common terminal 521 and each of the selection terminals 522 and 523 in the switching circuit 52.

Accordingly, the number of FETs of the switching circuit 51 for which higher electric power handling capability is required increases. Thereby, a downsizing effect by reducing the selection terminals of the switching circuit 51 is large.

Moreover, for example, in the radiofrequency circuit 1 according to this embodiment, the switching circuit 51 may further include the selection terminal 514. The radiofrequency circuit 1 may further include the transmission filter 33 and the reception filter 43. The transmission filter 33 is connected to the selection terminal 514 and has the pass band including the transmission band of the band C corresponding to the first power class. The reception filter 43 is connected to the selection terminal 522 and has the pass band including the reception band of the band C.

Accordingly, the reception filter 43 is further connected to the switching circuit 51 via the switching circuit 52. Thereby, the number of selection terminals of the switching circuit 51 can be reduced as compared with a case in which the reception filter 43 is directly connected to the selection terminal of the switching circuit 51. Therefore, off-capacitance of the selection terminal in the switching circuit 51 can be reduced, which can reduce loss of a transmission signal of the band C in addition to the band A.

Moreover, for example, in the radiofrequency circuit 1 according to this embodiment, when the band C is used in the first power class, the common terminal 511 may be connected to the selection terminal 514 and is not necessarily connected to the selection terminal 512. When the band C is used in the second power class, the common terminal 511 may be connected to the selection terminals 512 and 514, and the common terminal 521 may be connected to the selection terminal 522.

Accordingly, when the band C is used in the first power class, the common terminal 511 is not connected to the selection terminal 512. Therefore, since a transmission signal in the first power class is not transmitted to the switching circuit 52, electric power handling capability of the switching circuit 52 can be made lower than electric power handling capability of the switching circuit 51. As a result, an increase in size of the radiofrequency circuit 1 due to the switching circuit 52 can be suppressed, which can achieve downsizing of the radiofrequency circuit 1 as a result of downsizing of the switching circuit 51 by a reduction in the number of selection terminals of the switching circuit 51.

Moreover, for example, the radiofrequency circuit 1 according to this embodiment may further include the variable phase circuit 61 connected between the selection terminal 512 and the common terminal 521.

Accordingly, a phase shift amount of the variable phase circuit 61 can be changed between the case in which transmission and reception of a signal of the band A are performed simultaneously and the case in which transmission and reception of a signal of the band C are performed simultaneously. Therefore, when transmission and reception of a signal of the band A are performed simultaneously, the phase shift amount of the variable phase circuit 61 can be adjusted to a phase shift amount that can bring impedance in the transmission band of the band A closer to an open state when the reception filter 41 is seen from the common terminal 511. Moreover, when transmission and reception of a signal of the band C are performed simultaneously, the phase shift amount of the variable phase circuit 61 can be adjusted to a phase shift amount that can bring impedance in the transmission band of the band C closer to an open state when the reception filter 43 is seen from the common terminal 511. As a result, in simultaneous transmission and reception of a signal of the band A and simultaneous transmission and reception of a signal of the band C, it is possible to suppress intermodulation distortion and the like caused by leakage of a transmission signal to a reception path.

Moreover, for example, the radiofrequency circuit 1 according to this embodiment may further include the power amplifier 11 and the switching circuit 53. The switching circuit 53 includes the common terminal 531 connected to the power amplifier 11, the selection terminal 532 connected to the transmission filter 31, and the selection terminal 533 connected to the transmission filter 33.

Accordingly, the power amplifier 11 can be shared for amplification of transmission signals of the bands A and C, and a circuit scale of the radiofrequency circuit 1 can be reduced as compared with a case in which power amplifiers are individually prepared for the respective ones of the bands A and C.

Moreover, for example, in the radiofrequency circuit 1 according to this embodiment, the band A may be Band 1 for LTE or n1 for 5G NR. The band B may be Band 25 for LTE or n25 for 5G NR. The band C may be Band 3 for LTE or n3 for 5G NR.

Accordingly, the radiofrequency circuit 1 can support transmission and reception of a signal of Band 1 for LTE or n1 for 5G NR, transmission and reception of a signal of Band 25 for LTE or n25 for 5G NR, and transmission and reception of a signal of Band 3 for LTE or n3 for 5G NR.

Moreover, for example, the radiofrequency circuit 1 according to this embodiment may further include the module substrate 70 provided with the switching circuits 51 and 52, the transmission filter 31, and the reception filter 41. The switching circuits 51 and 52 may be disposed between the transmission filter 31 and the reception filter 41. The switching circuit 51 may be closer than the switching circuit 52 to the transmission filter 31. The switching circuit 52 may be closer than the switching circuit 51 to the reception filter 41.

Accordingly, the transmission filter 31 directly connected to the switching circuit 51 can be disposed close to the switching circuit 51, and the reception filter 41 directly connected to the switching circuit 52 can be disposed close to the switching circuit 52. As a result, a wiring length between the switching circuit 51 and the transmission filter 31 and a wiring length between the switching circuit 52 and the reception filter 41 can be shortened.

Moreover, for example, in the radiofrequency circuit 1 according to this embodiment, the switching circuit 51 may be implemented by CMOS-SOI.

Accordingly, electric power handling capability of the switching circuit 51 can be improved, and downsizing of the switching circuit 51 can be achieved. In some embodiments, the first switching circuit 51 and the second switching circuit 52 are integrated into a single semiconductor die, such as a Silicon-on-Insulator (SOI) or CMOS-SOI integrated circuit. In such an integrated embodiment, the first switching circuit 51 may be configured with a higher FET (Field Effect Transistor) stack count than the second switching circuit 52 to handle the higher voltage swings associated with the first power class (Power Class 2) while allowing the second switching circuit 52 to be optimized for lower insertion loss or smaller footprint for the second power class (Power Class 3).

### OTHER EMBODIMENTS

The radiofrequency circuit according to the present disclosure has been described based on the embodiment, but the radiofrequency circuit according to the present disclosure is not limited to the above embodiment. Other embodiments implemented by combination of any components in the above embodiment, modifications obtained by application, to the above embodiment, of various changes conceivable by the person skilled in the art without departing from the spirit of the present disclosure, and various devices including therein the radiofrequency circuit described above are also included in the present disclosure.

For example, in the circuit configuration of the radiofrequency circuit according to each embodiment described above, another circuit element, wiring, and the like may be inserted in a path connecting each circuit element and the signal path disclosed in the drawings. For example, an impedance matching circuit may be inserted between a filter and a switching circuit.

Moreover, for example, the radiofrequency circuit according to each embodiment described above may further include one or more transmission filters and/or one or more reception filters. In this case, the switching circuits 51 and/or 52 may further include one or more additional selection terminals to which the one or more transmission filters and/or the one or more reception filters are connected.

Features of the radiofrequency circuit described based on the above embodiments are described below.
<1>

A radiofrequency circuit including:
a first switching circuit including a first common terminal connected to an antenna connection terminal, a first selection terminal, and a second selection terminal;
a second switching circuit including a second common terminal connected to the first selection terminal, a third selection terminal, and a fourth selection terminal;
a first transmission filter connected to the second selection terminal and having a pass band including a transmission band of a first FDD band corresponding to a first power class defined by first maximum output power;
a first reception filter connected to the third selection terminal and having a pass band including a reception band of the first FDD band; and
at least one of a second transmission filter and a second reception filter connected to the fourth selection terminal, the second transmission filter having a pass band including a transmission band of a second band corresponding to a second power class defined by second maximum output power lower than the first maximum output power, the second reception filter having a pass band including a reception band of a third band.
<2>

The radiofrequency circuit according to <1>, in which
when the first FDD band is used in the first power class, the first common terminal is connected to the second selection terminal and is not connected to the first selection terminal, and
when the first FDD band is used in the second power class, the first common terminal is connected to the first selection terminal and the second selection terminal, and the second common terminal is connected to the third selection terminal.
<3>

The radiofrequency circuit according to <1> or <2>, in which
the number of a plurality of FETs connected in series between the first common terminal and each of the first selection terminal and the second selection terminal in the first switching circuit is greater than the number of a plurality of FETs connected in series between the second common terminal and each of the third selection terminal and the fourth selection terminal in the second switching circuit.
<4>

The radiofrequency circuit according to any one of <1> to <3>, in which
the first switching circuit further includes a fifth selection terminal, and
the radiofrequency circuit further includes
   a third transmission filter connected to the fifth selection terminal and having a pass band including a transmission band of a fourth FDD band corresponding to the first power class, and
   a third reception filter connected to the third selection terminal and having a pass band including a reception band of the fourth FDD band.
<5>

The radiofrequency circuit according to <4>, in which
when the fourth FDD band is used in the first power class, the first common terminal is connected to the fifth selection terminal and is not connected to the first selection terminal, and
when the fourth FDD band is used in the second power class, the first common terminal is connected to the first selection terminal and the fifth selection terminal, and the second common terminal is connected to the third selection terminal.
<6>

The radiofrequency circuit according to <4> or <5>, further including:
a variable phase circuit connected between the first selection terminal and the second common terminal.
<7>

The radiofrequency circuit according to any one of <4> to <6>, further including:
a power amplifier; and
a third switching circuit including a third common terminal connected to the power amplifier, a sixth selection terminal connected to the first transmission filter, and a seventh selection terminal connected to the third transmission filter.
<8>

The radiofrequency circuit according to any one of <4> to <7>, in which
the first FDD band is Band 1 for LTE or n1 for 5G NR,
the second band and the third band are both Band 25 for LTE or n25 for 5G NR, and
the fourth FDD band is Band 3 for LTE or n3 for 5G NR.
<9>

The radiofrequency circuit according to any one of <1> to <8>, further including:
a module substrate provided with the first switching circuit, the second switching circuit, the first transmission filter, and the first reception filter, in which
the first switching circuit and the second switching circuit are disposed between the first transmission filter and the first reception filter,
the first switching circuit is closer than the second switching circuit to the first transmission filter, and
the second switching circuit is closer than the first switching circuit to the first reception filter.
<10>

The radiofrequency circuit according to any one of <1> to <9>, in which
the first switching circuit is implemented by CMOS-SOI.

### INDUSTRIAL APPLICABILITY

The present disclosure can widely be used in communication equipment, such as a cellular phone, as a radiofrequency circuit disposed at a front-end portion.

### REFERENCE SIGNS LIST

1 radiofrequency circuit
2 antenna
3 RFIC
4 BBIC
5 communication device
11, 12 power amplifier
21, 22, 23 low noise amplifier
31, 32, 33 transmission filter
41, 42, 43 reception filter
50 integrated circuit
51, 52, 53 switching circuit
61 variable phase circuit
70 module substrate
101 antenna connection terminal
111, 112 radiofrequency input terminal
121, 122, 123 radiofrequency output terminal
511, 521, 531 common terminal
512, 513, 514, 522, 523, 532, 533 selection terminal
D11, D12, D21, D22 distance

1. A radiofrequency circuit comprising:
a first switching circuit including a first common terminal connected to an antenna connection terminal, a first selection terminal, and a second selection terminal;
a second switching circuit including a second common terminal connected to the first selection terminal, a third selection terminal, and a fourth selection terminal;
a first transmission filter connected to the second selection terminal and having a pass band including a transmission band of a first frequency division duplex (FDD) band corresponding to a first power class defined by first maximum output power;
a first reception filter connected to the third selection terminal and having a pass band including a reception band of the first FDD band; and
at least one of a second transmission filter and a second reception filter connected to the fourth selection terminal, the second transmission filter having a pass band including a transmission band of a second band corresponding to a second power class defined by second maximum output power lower than the first maximum output power, the second reception filter having a pass band including a reception band of a third band.

2. The radiofrequency circuit according to claim 1, wherein
when the first FDD band is used in the first power class, the first common terminal is connected to the second selection terminal and is not connected to the first selection terminal, and
when the first FDD band is used in the second power class, the first common terminal is connected to the first selection terminal and the second selection terminal, and the second common terminal is connected to the third selection terminal.

3. The radiofrequency circuit according to claim 1, wherein
the number of a plurality of FETs connected in series between the first common terminal and each of the first selection terminal and the second selection terminal in the first switching circuit is greater than the number of a plurality of FETs connected in series between the second common terminal and each of the third selection terminal and the fourth selection terminal in the second switching circuit.

4. The radiofrequency circuit according to claim 1, wherein
the first switching circuit further includes a fifth selection terminal, and
the radiofrequency circuit further includes
a third transmission filter connected to the fifth selection terminal and having a pass band including a transmission band of a fourth FDD band corresponding to the first power class, and
a third reception filter connected to the third selection terminal and having a pass band including a reception band of the fourth FDD band.

5. The radiofrequency circuit according to claim 4, wherein
when the fourth FDD band is used in the first power class, the first common terminal is connected to the fifth selection terminal and is not connected to the first selection terminal, and
when the fourth FDD band is used in the second power class, the first common terminal is connected to the first selection terminal and the fifth selection terminal, and the second common terminal is connected to the third selection terminal.

6. The radiofrequency circuit according to claim 4, further comprising:
a variable phase circuit connected between the first selection terminal and the second common terminal.

7. The radiofrequency circuit according to claim 4, further comprising:
a power amplifier; and
a third switching circuit including a third common terminal connected to the power amplifier, a sixth selection terminal connected to the first transmission filter, and a seventh selection terminal connected to the third transmission filter.

8. The radiofrequency circuit according to claim 4, wherein
the first FDD band is Band 1 for LTE or n1 for 5G NR,
the second band and the third band are both Band 25 for LTE or n25 for 5G NR, and
the fourth FDD band is Band 3 for LTE or n3 for 5G NR.

9. The radiofrequency circuit according to claim 1, further comprising:
a module substrate provided with the first switching circuit, the second switching circuit, the first transmission filter, and the first reception filter, wherein
the first switching circuit and the second switching circuit are disposed between the first transmission filter and the first reception filter,
the first switching circuit is closer than the second switching circuit to the first transmission filter, and
the second switching circuit is closer than the first switching circuit to the first reception filter.

10. The radiofrequency circuit according to claim 1, wherein
the first switching circuit is implemented by complementary metal-oxide-semiconductor silicon-on-insulator (CMOS-SOI).

11. The radio-frequency circuit according to claim 1, further comprising a third switching circuit and a power amplifier, the third switching circuit configured to selectively connect the power amplifier to the first transmission filter.

12. The radio-frequency circuit of claim 1, further comprising circuitry configured to adjust a phase shift amount of a variable phase circuit connected between the first selection terminal and the second common terminal.

13. A radio frequency circuit comprising:
a first switching circuit connected to an antenna connection terminal;
a first transmission filter connected to a selection terminal of the first switching circuit and configured for a first power class;
a second switching circuit connected to a different selection terminal of the first switching circuit; and
a first reception filter connected to the second switching circuit, wherein
the first switching circuit includes circuitry configured to connect the first transmission filter to the antenna connection terminal and disconnect the second switching circuit from the antenna connection terminal in a first communication mode.

14. The radio-frequency circuit according to claim 13, wherein a power handling capability of the first switching circuit is higher than a power handling capability of the second switching circuit.

15. The radio-frequency circuit according to claim 13, wherein the first transmission filter is a bulk acoustic wave (BAW) filter and the first reception filter is a surface acoustic wave (SAW) filter.

16. The radio-frequency circuit according to claim 13, wherein the first communication mode corresponds to a Power Class 2 transmission.

17. The radio-frequency circuit according to claim 16, wherein the first switching circuit is configured to connect both the first transmission filter and the second switching circuit to the antenna connection terminal in a second communication mode corresponding to a Power Class 3 transmission.

18. A radio frequency module comprising:
a module substrate;
a first switching circuit, a second switching circuit, a first transmission filter, and a first reception filter disposed on the module substrate, wherein
the first switching circuit and the second switching circuit are disposed between the first transmission filter and the first reception filter in a plan view of the module substrate, and
a first distance between the first switching circuit and the first transmission filter is shorter than a second distance between the second switching circuit and the first transmission filter.

19. The radio frequency module according to claim 18, wherein the first switching circuit and the second switching circuit are implementation in a single integrated circuit.

20. The radio frequency module according to claim 18, wherein a wiring length between the first switching circuit and the first transmission filter is shorter than a wiring length between the second switching circuit and the first transmission filter.
